(19) United States
(12) Patent Application Publication
(10) Pub. No.: US 2026/0271594 A1
(43) Pub. Date: Sep. 10, 2026

(54) DISPLAY DEVICE AND ELECTRONIC DEVICE INCLUDING THE SAME

(71) Applicant: Samsung Display Co., Ltd., Yongin-si (KR)

(72) Inventor: Changho Hyun, Yongin-si (KR)

(21) Appl. No.: 19/555,650

(22) Filed: Mar. 3, 2026

(30) Foreign Application Priority Data
Mar. 4, 2025 (KR) 10-2025-0027670

(51) Int. Cl. H10K 59/80; H10H 29/855; H10K 59/65

(52) U.S. Cl. CPC H10K 59/879; H10H 29/855; H10K 59/65

(57) ABSTRACT

A display device includes: a display panel including a transmission area and a first display area surrounding the transmission area; a prism unit comprising four triangular prisms and located below the transmission area; a second display area spaced apart from the prism unit in a first direction; a camera unit arranged spaced apart from the prism unit in the first direction; and a sensor unit below the prism unit, wherein a first side surface and a second side surface of the prism are film-coated.

### CROSS-REFERENCE TO RELATED APPLICATION

The present application claims priority to and the benefit of Korean Patent Application No. 10-2025-0027670, filed on March 4, 2025, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

A display device visually displays data. The display device may display images using light-emitting diodes. As uses of display devices are becoming more diverse, various designs have been attempted to improve the quality of display devices.

The above information disclosed in this Background section is only for enhancement of understanding of the background and therefore the information discussed in this Background section does not necessarily constitute prior art.

### SUMMARY

Additional aspects will be set forth in part in the description which follows and, in part, will be apparent from the description, or may be learned by practice of the presented embodiments of the disclosure.

According to one or more embodiments, a display device includes a display panel including a transmission area and a first display area surrounding the transmission area, a prism unit including four triangular prisms and located below the transmission area, a second display area spaced apart from the prism unit in a first direction, a camera unit spaced apart from the prism unit in the first direction, and a sensor unit below the prism unit, wherein a first side surface and a second side surface of the prism are film-coated.

According to some embodiments, the prism unit may have a shape so that first side surfaces or second side surfaces of the four prisms are in contact with each other.

According to some embodiments, the prism unit may have a hexahedral shape.

According to some embodiments, the first display area may include a first display element, wherein the first display element may include a first light-emitting diode and a first pixel circuit electrically connected to the first light-emitting diode.

According to some embodiments, the second display area may include a second display element, wherein the second display element may include a second light-emitting diode and a second pixel circuit electrically connected to the second light-emitting diode.

According to some embodiments, a number of the second display elements per unit area in the second display area may be equal to a number of the first display elements per unit area in the first display area.

According to some embodiments, light transmitted through the transmission area may be reflected from the first side surface or the second side surface of the prism of the prism unit and may enter the camera unit.

According to some embodiments, light transmitted through the transmission area may be transmitted through the first side surface or the second side surface of the prism of the prism unit and may enter the sensor unit.

According to some embodiments, light emitted from the second display area may be reflected from the first side surface or the second side surface of the prism of the prism unit and may enter the transmission area.

According to some embodiments, when the camera unit is driven, the second display element of the second display area may not be driven.

According to some embodiments, when the sensor unit is driven, the second display element of the second display area may not be driven.

According to some embodiments, when the second display element of the second display area is driven, the camera unit and the sensor unit may not be driven.

According to some embodiments, the display panel may include a first edge area extending from the first display area.

According to some embodiments, the first edge area may be arranged on one side of the first display area.

According to some embodiments, the display panel may include a second edge area extending from the first edge area and located below the first display area.

According to some embodiments, the second edge area may include the second display area.

According to one or more embodiments, an electronic device includes a display panel including a transmission area and a first display area surrounding the transmission area, a prism unit including four triangular prisms and located below the transmission area, a second display area spaced apart from the prism unit in a first direction, a camera unit spaced apart from the prism unit in the first direction, and a sensor unit below the prism unit, wherein a first side surface and a second side surface of the prism are film-coated, and the prism unit has a shape so that the first side surface or the second side surface of each of the four prisms are in contact with each other.

According to some embodiments, a number of second display elements per unit area in the second display area may be equal to a number of the first display elements per unit area in the first display area.

According to some embodiments, the display panel may include a first edge area extending to the first display area and a second edge area extending from the first edge area and located below the first display area.

According to some embodiments, the second edge area may include a second display area.

### BRIEF DESCRIPTION OF THE DRAWINGS

The above and other aspects, features, and characteristics of certain embodiments of the present disclosure will be more apparent from the following description taken in conjunction with the accompanying drawings, in which:

FIG. 1 is a block diagram of an electronic device according to some embodiments;

FIG. 2 is a schematic diagram of an electronic device according to some embodiments;

FIG. 3 is a perspective view showing a display device according to some embodiments;

FIG. 4 is an exploded perspective view showing a display device according to some embodiments;

FIG. 5 is a schematic diagram of a pixel circuit electrically connected to a light-emitting diode included in a display panel according to some embodiments;

FIG. 6 is a schematic equivalent circuit diagram of a pixel circuit electrically connected to a light-emitting diode included in a display panel according to some embodiments;

FIG. 7 is a schematic front view of a display panel according to some embodiments;

FIG. 8 is a schematic cross-sectional view of a second display area of a display panel according to some embodiments;

FIG. 9 is a schematic side view of a display device according to some embodiments;

FIG. 10 is a schematic rear view of a display device according to some embodiments;

FIG. 11 is a schematic cross-sectional view of a first display area and a transmission area of a display device according to some embodiments;

FIG. 12 is a schematic perspective view showing a prism unit including four prisms;

FIG. 13 includes schematic perspective views showing paths of light when a camera unit, a sensor unit, and a second display area are driven; and

FIG. 14 includes a schematic cross-sectional view showing an arrangement of a first display element in a first display area and a schematic cross-sectional view showing an arrangement of a second display element in a second display area.

### DETAILED DESCRIPTION

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure may, however, be embodied in many different forms and should not be construed as being limited to the embodiments set forth herein.

In the following embodiments, while such terms as "first," "second," etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as "including" and "having" are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it may be directly or indirectly formed on the other layer, region, or element. That is, for example, intervening layers, regions, or elements may be present.

Sizes of elements in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, "A and/or B" may include "A," "B," or "A and B". And, “at least one of A and B” indicates the case of A, B, or A and B.

It will be understood that when a layer, region, or component is referred to as being connected to another layer, region, or component, it may be directly or indirectly connected to the other layer, region, or component. That is, for example, intervening layers, regions, or components may be present. For example, it will be understood that when a layer, region, or component is referred to as being electrically connected to another layer, region, or component, it may be directly or indirectly electrically connected to the other layer, region, or component. That is, for example, intervening layers, regions, or components may be present.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

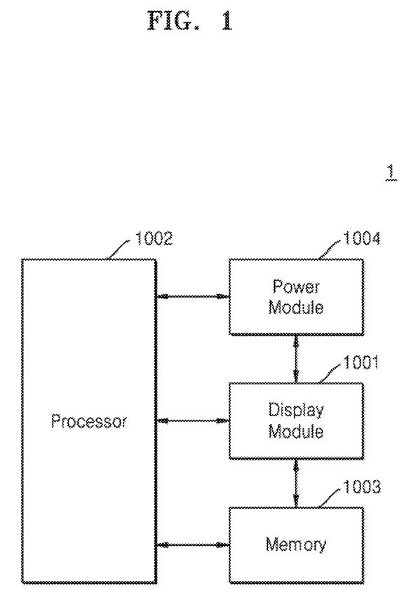

FIG. 1 is a block diagram of an electronic device according to some embodiments.

Referring to FIG. 1, a display device 1 according to some embodiments may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), or a controller.

Data information necessary for operation of the processor 1002 or the display module 1001 may be stored in a memory 1003. When the processor 1002 executes an application stored in the memory 1003, an image data signal and/or an input control signal is transmitted to the display module 1001, and the display module 1001 may process the received signal and output image information on a display screen.

The power module 1004 may include a power supply module, such as a power adapter or a battery device, and a power conversion module that converts power supplied by the power supply module to generate power required for the operation of the display device 1.

At least one of the components of the display device 1 may be included in the display panel according to embodiments. Additionally, some of the individual modules functionally included within a single module may be included within the display panel, while others may be provided separately from the display panel. For example, the display panel may include the display module 1001, and the processor 1002, the memory 1003, and the power module 1004 may be provided in the form of other devices within the display device 1 other than the display panel.

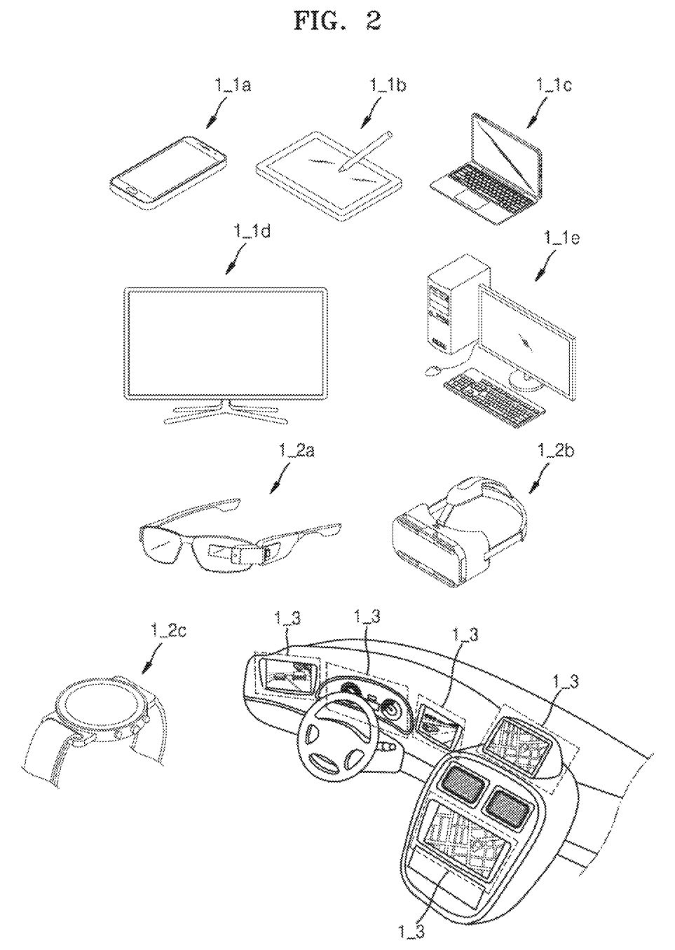

FIG. 2 is a schematic diagram of an electronic device according to various embodiments.

Referring to FIG. 2, various electronic devices to which display devices according to some embodiments are applied may include not only image display electronic devices such as a smart phone 1_1a, a tablet PC 1_1b, a laptop 1_1c, a TV 1_1d, and a desk monitor 1_1e, but also wearable electronic devices including display modules such as smart glasses 1_2a, a head mounted display 1_2b, and a smart watch 1_2c, and vehicle electronic devices 1_3 including display modules such as a center information display (CID) and a room mirror display arranged on a dashboard, center fascia, and car instrument panel.

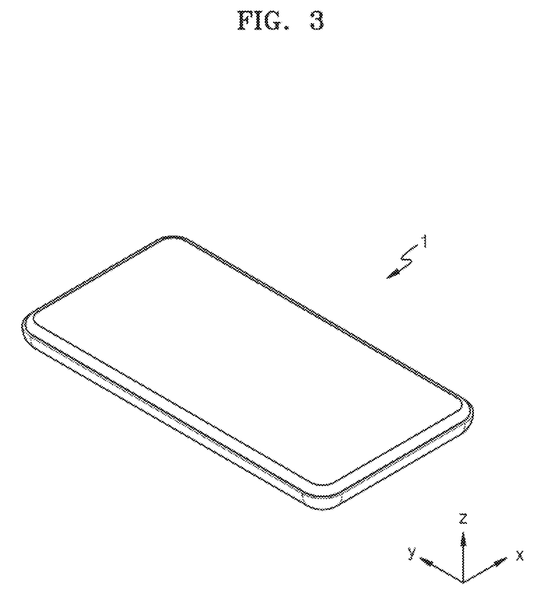

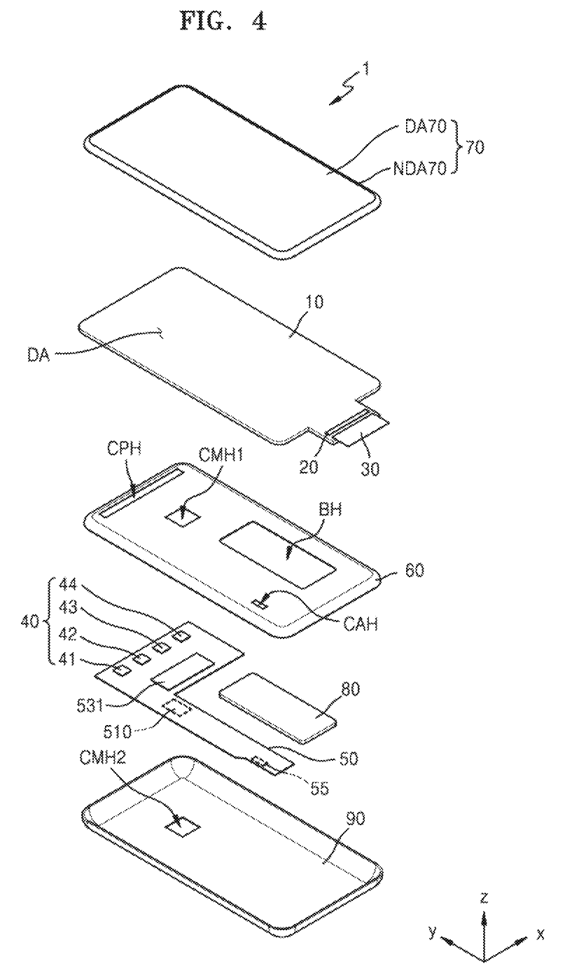

FIG. 3 is a perspective view showing a display device according to some embodiments, and FIG. 4 is an exploded perspective view showing a display device according to some embodiments.

Referring to FIGS. 3 and 4, the display device 1 according to some embodiments is illustrated as being used as a smart phone. The display device 1 according to some embodiments may include a cover window 70, a display panel 10, a data driver 20, a display circuit board 30, a component 40, a bracket 60, a main circuit board 50, a battery 80, and a lower cover 90.

In a plain view of this specification, “left”, “right”, “up”, and “down” indicate the direction when looking at the display panel 10 from a vertical direction of the display panel 10. For example, "left" points in -x direction, "right" points in +x direction, "up" points in +y direction, and "down" points in -y direction.

The display device 1 may be formed in a rectangular shape on a flat surface. For example, the display device 1 may be formed in a rectangular planar shape having a short side in the x direction and a long side in the y direction, as shown in FIG. 3. The corner where the short side in the x direction and the long side in the y direction meet may be formed rounded to have a curvature (e.g., a set or predetermined curvature) or may be formed at a right angle. The flat shape of the display device 1 is not limited to a rectangle, and may be formed into other polygonal, elliptical, or irregular shapes.

The cover window 70 may be located on the upper part of the display panel 10 to cover an upper surface of the display panel 10. Due to this, the cover window 70 may function to protect the upper surface of the display panel 10.

The cover window 70 may include a transmission cover portion DA70 corresponding to the display panel 10 and a light-blocking cover portion NDA70 surrounding the transmission cover portion DA70. The light-blocking cover portion NDA70 may include an opaque material (e.g., a colored opaque material) that blocks light. The light-blocking cover portion NDA70 may include a pattern that may be displayed to the user when the image is not displayed.

The display panel 10 may be located below the cover window 70 to provide an image. The display panel 10 may overlap with the transmission cover portion DA70 of the cover window 70.

The display panel 10 may include a display area DA. The display area DA may be an area where an image is displayed, and the display area DA may include an area (hereinafter, component area) that transmits light emitted from the component 40 located below the display panel 10. The component 40 may include sensors, cameras, etc. that use visible light, infrared, or sound.

The display panel 10 may display (outputs) information processed in the display device 1. For example, the display panel 10 may display execution screen information of an application driven on the display device 1, or UI (User Interface) or GUI (Graphical User Interface) information according to the execution screen information.

The display panel 10 may be a light-emitting display panel including a light-emitting diode. The light-emitting diode may include an organic light-emitting diode including an organic light-emitting layer. In some embodiments, the light-emitting diode may be an inorganic light-emitting diode including an inorganic material. The inorganic light-emitting diode may include a PN diode including inorganic semiconductor-based materials. When voltage is applied in the forward direction to a PN junction diode, holes and electrons may be injected, and the energy generated by the recombination of the holes and electrons may be converted into light energy, which may emit light of a certain color. The aforementioned inorganic light-emitting diodes may have a width of several to several hundred micrometers, and in some embodiments, the inorganic light-emitting diodes may be referred to as micro LEDs.

The display panel 10 may be a rigid display panel that is rigid and does not bend easily, or a flexible display panel that is flexible and may be easily bent, folded, or rolled. For example, the display panel 10 may be a foldable display panel that may be folded and unfolded, a curved display panel with a curved display surface, a bent display panel with a curved area other than the display surface, a rollable display panel that may be rolled and unfolded, and a stretchable display panel that may be stretched.

The display panel 10 may be implemented transparent and may be a transmission display panel that allows objects or backgrounds displaced on a lower surface of the display panel 10 to be viewed from the upper surface of the display panel 10. Alternatively, the display panel 10 may be a reflective display panel capable of reflecting an object or background on the upper surface of the display panel 10.

The data driver 20 may be placed on the display panel 10 in the form of an integrated circuit (IC). According to some embodiments, the data driver 20 may be located on the display circuit board 30.

The display circuit board 30 may be attached to one side of the display panel 10. The display circuit board 30 may be a flexible printed circuit board (FPCB) that may be bent, a rigid printed circuit board (PCB) that is hard and does not bend easily, or a composite printed circuit board including both a rigid printed circuit board and a flexible printed circuit board.

According to some embodiments, a touch sensor driver may be located on the display circuit board 30. The touch sensor driver may be formed as the integrated circuit. The touch sensor driving unit may be attached to the display circuit board 30. The touch sensor driver may be electrically connected to touch electrodes of touch screen layer of the display panel 10 through the display circuit board 30.

The touch screen layer of the display panel 10 may detect a user's touch input using at least one of various touch methods, such as a resistive film method or an electrostatic capacitance method. For example, when the touch screen layer of the display panel 10 detects the user's touch input in a capacitive manner, the touch sensor driver may apply driving signals to the driving electrodes among the touch electrodes, and may detect voltages charged in mutual capacitances (hereinafter referred to as "mutual capacitance") between the driving electrodes and the sensing electrodes through the sensing electrodes among the touch electrodes, thereby determining whether the user has touched. A user's touch may include contact touch and proximity touch. Contact touch refers to direct contact between a user's finger or an object such as a pen and the cover window 70 located on a touch screen layer. Proximity touch refers to a situation where a user's finger or an object such as a pen is positioned close to the cover window 70, such as hovering. The touch sensor driver transmits sensor data to a main processor 510 according to the detected voltages, and the main processor 510 may analyze the sensor data to calculate the touch coordinates where the touch input occurred.

A control unit for supplying driving voltages for driving pixels, a gate driver, and the data driver 20 of the display panel 10 may be placed on the display circuit board 30.

A bracket 60 for supporting the display panel 10 may be placed at the bottom of the display panel 10. The bracket 60 may include plastic, metal, or both plastic and metal. A first camera hole CMH1 into which a camera device 531 is inserted, a battery hole BH into which a battery 80 is placed, and a cable hole CAH through which a cable connected to the display circuit board 30 passes may be formed in the bracket 60. The bracket 60 may be provided with a component hole CPH that overlaps the display panel 10. The component hole CPH may overlap with the component 40 of the main circuit board 50 in the third direction (z direction). According to some embodiments, the display area DA of the display panel 10 may overlap the component 40 of the main circuit board 50 in the third direction (z direction). According to some embodiments, the bracket 60 may not have the component hole CPH formed therein.

According to some embodiments, the component 40 may include first to fourth component 41, 42, 43, 44 overlapping the display panel 10. The first to fourth components 41, 42, 43, 44 may each be equipped with a proximity sensor, a light sensor, an iris sensor, a facial recognition sensor, and a camera (or image sensor). A proximity sensor using infrared rays may detect an object placed close to the upper surface of the display device 1, and a light sensor may detect the brightness of light incident on the upper surface of the display device 1. Additionally, the iris sensor may capture an iris of a person placed on the upper surface of the display device 1, and the camera may capture an object placed on the upper surface of the display device 1. The component 40 is not limited to a proximity sensor, a light sensor, an iris sensor, a facial recognition sensor, and a camera, and various other sensors may be placed.

The main circuit board 50 and the battery 80 may be located below the bracket 60. The main circuit board 50 may be a printed circuit board or a flexible printed circuit board.

The main circuit board 50 may include a main processor 510, a camera device 531, a main connector 55 and the component 40. The main processor 510 may be formed as an integrated circuit. The camera device 531 may be located on both upper and lower surfaces of the main circuit board 50, and each of the main processor 510 and the main connector 55 may be located on either the upper or lower surface of the main circuit board 50.

The main processor 510 may control all functions of the display device 1. For example, the main processor 510 may output digital video data to the data driver 20 via the display circuit board 30 so that the display panel 10 displays an image. The main processor 510 may receive detection data from the touch sensor driving unit. The main processor 510 may determine whether the user has touched the sensor based on the detection data and execute an action corresponding to the user's direct touch or proximity touch. The main processor 510 may be an application processor, a central processing unit, or a system chip made of an integrated circuit.

The camera device 531may process image frames, such as still images or moving images, obtained by an image sensor in camera mode and may output them to the main processor 510. The camera device 531 may include at least one of a camera sensor (e.g., CCD, CMOS, etc.), a photo sensor (or image sensor), or a laser sensor. The camera device 531 is connected to an image sensor among the component 40 overlapping the second display area DA2 and may process an image input to the image sensor.

A cable 35 passing through the cable hole CAH of the bracket 60 may be connected to the main connector 55, so that the main circuit board 50 may be electrically connected to the display circuit board 30.

The cable 35 passing through the cable hole CAH of the bracket 60 may be connected to the main connector 55, so that the main circuit board 50 may be electrically connected to the display circuit board 30.

The battery 80 may be arranged so as not to overlap the main circuit board 50 in the third direction (z direction). The battery 80 may be overlapped with a battery hole (BH) of the bracket 60.

The lower cover 90 forms the exterior of the display device 1 and may have an opening exposing a portion of the display panel 10 on the front surface. The lower cover 90 has an open shape corresponding to the display panel 10 and may be assembled with the display panel 10. The lower cover 90 may be located on the opposite side of the cover window 70 with the display panel 10 interposed therebetween. The lower cover 90 may be located under the main circuit board 50 and the battery 80. The lower cover 90 may be fixed by being connected to the bracket 60. The lower cover 90 may form the lower surface appearance of the display device 1. The lower cover 90 may include plastic, metal, or both plastic and metal.

A second camera hole CMH2 that exposes the lower surface of the camera device 531 may be formed in the lower cover 90. The position of the camera device 531 and the positions of the first and second camera holes CMH1 and CMH2 corresponding to the camera device 531 are not limited to the embodiments shown in FIGS. 3 and 4 and may be changed in various ways.

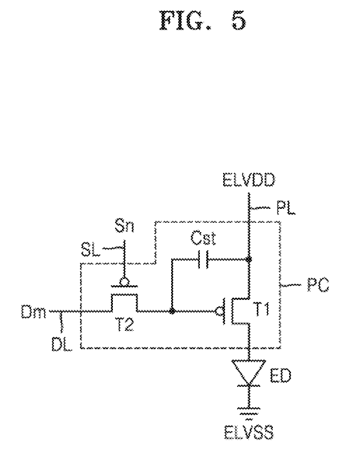

FIG. 5 schematically illustrates a pixel circuit electrically connected to a light-emitting diode that may be included in a display panel according to some embodiments. Although FIG. 5 illustrates various components in a pixel circuit PC according to some embodiments, embodiments according to the present disclosure are not limited thereto, and according to various embodiments, the pixel circuit may include additional components without departing from the spirit and scope of embodiments according to the present disclosure.

Referring to FIG. 5, a pixel circuit PC may include a first transistor T1, a second transistor T2, and a storage capacitor Cst. The first transistor T1 may be a driving transistor, and the second transistor T2 may be a data writing transistor.

The second transistor T2 is connected to a scan line SL and a data line DL, and may transmit the data voltage (or data signal, Dm) input from the data line DL to the first transistor T1 based on the switching voltage (or switching signal, Sn) input from the scan line SL. The storage capacitor Cst is connected to the second transistor T2 and the driving voltage line PL, and may store a voltage corresponding to the difference between the voltage received from the second transistor T2 and a driving voltage ELVDD supplied to the driving voltage line PL.

The first transistor T1 is connected to the driving voltage line PL and the storage capacitor Cst, and may control a driving current flowing through a light-emitting diode ED from the driving voltage line PL in response to a voltage value stored in the storage capacitor Cst. The light-emitting diode ED may emit light with a certain brightness depending on the driving current. The counter electrode (e.g., cathode) of the light-emitting diode ED may be supplied with a common voltage ELVSS.

FIG. 5 illustrates that the pixel circuit PC includes two thin film transistors and one storage capacitor, but the disclosure is not limited thereto. The number of thin film transistors and the number of storage capacitors may vary depending on the design of the pixel circuit PC. For example, a pixel circuit PC may include three, four, five or more thin film transistors. Additionally, the pixel circuit PC may include multiple capacitors.

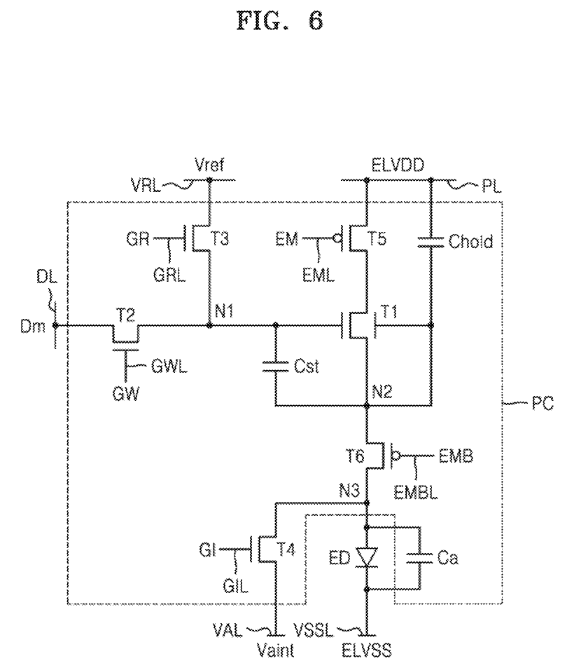

FIG. 6 is an equivalent circuit diagram schematically illustrating a pixel circuit electrically connected to a light-emitting diode that may be included in a display panel according to some embodiments. Although FIG. 6 illustrates various components in a pixel circuit PC according to some embodiments, embodiments according to the present disclosure are not limited thereto, and according to various embodiments, the pixel circuit may include additional components, or fewer components, without departing from the spirit and scope of embodiments according to the present disclosure.

Referring to FIG. 6, the pixel circuit PC may be electrically connected to a first gate line GWL transmitting a first gate signal GW, a second gate line GRL transmitting a second gate signal GR, a third gate line EML transmitting a third gate signal EM, a fourth gate line GIL transmitting a fourth gate signal GI, a fifth gate line EMBL transmitting a fifth gate signal EMB, and a data line DL transmitting a data signal Dm. Because a light emission of the light-emitting diode ED is controlled by the third gate signal EM and the fifth gate signal EMB, the third gate signal EM and the fifth gate signal EMB may be referred to as light emission control signals, and the third gate line EML and the fifth gate line EMBL may be referred to as light emission control lines. The pixel circuit PC may be electrically connected to a driving voltage line PL that transmits a driving voltage ELVDD, a reference voltage line VRL that transmits a reference voltage Vref, and an initialization voltage line VAL that transmits an initialization voltage Vaint.

According to some embodiments, some of the plurality of transistors included in the pixel circuit PC may be N-type transistors and others may be P-type transistors. First to fourth transistors T1, T2, T3, and T4 may be N-type transistors, and fifth and sixth transistors T5 and T6 may be P-type transistors. The semiconductor layers of the first to fourth transistors T1, T2, T3, and T4 may include a different material from the semiconductor layers of the fifth and sixth transistors T5 and T6. In some embodiments, the first to fourth transistors T1, T2, T3, and T4 may include oxide semiconductor materials, and the fifth and sixth transistors T5 and T6 may include amorphous silicon, polysilicon, or organic semiconductors.

The pixel circuit PC may include the first to sixth transistors T1, T2, T3, T4, T5, and T6, a storage capacitor Cst, a holding capacitor Chold, and an auxiliary capacitor Ca. The first transistor T1 is a driving transistor that outputs a driving current corresponding to the data signal Dm, and the second to sixth transistors T2, T3, T4, T5, and T6 may be switching transistors that transmit signals. The first transistor T1 may be referred to as a driving transistor, the second transistor T2 as a data writing transistor, the third transistor T3 as a compensation transistor, the fourth transistor T4 as an initialization transistor, the fifth transistor T5 as an operation control transistor, and the sixth transistor T6 as an emission control transistor.

A first terminal (or first electrode) and a second terminal (or second electrode) of each of the first to sixth transistors T1, T2, T3, T4, and T5, and T6 may be a source (or source electrode) or a drain (or drain electrode) depending on the voltage of the first terminal and the second terminal. For example, depending on the voltages at the first terminal and the second terminal, the first terminal may be a drain and the second terminal may be a source, or the first terminal may be a source and the second terminal may be a drain. Hereinafter, a node to which a first-first gate electrode of the first transistor T1 is connected may be defined as a first node N1, and a node to which the second terminal of the first transistor T1 is connected may be defined as a second node (N2).

The first transistor T1may be connected to the driving voltage line PL and the light-emitting diode ED. The first transistor T1 may be connected between the fifth transistor T5 and the sixth transistor T6. The first transistor T1 may include a first gate (or a first gate electrode), the first terminal, and the second terminal connected to the second node N2. The first transistor T1 may include the first-first gate connected to the first node N1. The first transistor T1 may further include a first-second gate connected to its second terminal. The first-first gate and the first-second gate may be arranged to face each other on different layers. For example, the first-first gate and the first-second gate of the first transistor T1 may face each other with a semiconductor layer between them. In this specification, the first gate (or first gate electrode) of the first transistor T1 may refer to the first-first gate (or first-first gate electrode) involved in turning on and off the first transistor T1.

The gate (or first-first gate) of the first transistor T1 may be connected to the second terminal of the second transistor T2, a first terminal of the third transistor T3, and the storage capacitor Cst. The first-second gate of the first transistor T1 may be connected to a first terminal of the sixth transistor T6, the storage capacitor Cst, and the holding capacitor Chold. The first terminal of the first transistor T1 may be connected to the driving voltage line PL via the fifth transistor T5, and the second terminal may be connected to the pixel electrode of the light-emitting diode ED via the sixth transistor T6. The first terminal of the first transistor T1 may be connected to a second terminal of the fifth transistor T5. The second terminal of the first transistor T1 may be connected to the first terminal of the sixth transistor T6, the storage capacitor Cst, and the holding capacitor Chold. The first transistor T1 may receive the data signal Dm according to the switching operation of the second transistor T2 and control the amount of driving current flowing to the light-emitting diode ED.

The second transistor T2 may be connected to the data line DL and the gate of the first transistor T1. The second transistor T2 may include a gate connected to the first gate line GWL, a first terminal connected to the data line DL, and a second terminal connected to the first node N1. The second terminal of the second transistor T2 may be connected to the gate of the first transistor T1, a first terminal of the third transistor T3, and the storage capacitor Cst. The second transistor T2 is turned on by the first gate signal GW transmitted to the first gate line GWL to electrically connect the data line DL and the first node N1, and may transmit the data signal Dm transmitted to the data line DL to the first node N1.

The third transistor T3 may be connected to the gate of the first transistor T1 and the reference voltage line VRL. The third transistor T3 may include a gate connected to the second gate line GRL, the first terminal connected to the first node N1, and a second terminal connected to the reference voltage line VRL. The first terminal of the third transistor T3 may be connected to the gate of the first transistor T1, the second terminal of the second transistor T2, and the storage capacitor Cst. The third transistor T3 is turned on by the second gate signal GR transmitted to the second gate line GRL and may transmit the reference voltage Vref transmitted to the reference voltage line VRL to the first node N1.

The fourth transistor T4 may be connected to the sixth transistor T6 and the initialization voltage line VAL. The fourth transistor T4 may be connected between the light-emitting diode ED and the initialization voltage line VAL. The fourth transistor T4 may include a gate connected to the fourth gate line GIL, a first terminal connected to a third node N3, and a second terminal connected to the initialization voltage line VAL. The first terminal of the fourth transistor T4 may be connected to a second terminal of the sixth transistor T6 and the pixel electrode of the light-emitting diode ED. The fourth transistor T4 is turned on by the fourth gate signal GI transmitted to the fourth gate line GIL and may transmit the first initialization voltage Vaint transmitted to the initialization voltage line VAL to the third node N3 and initialize the pixel electrode (e.g., anode) of the light-emitting diode ED.

The fifth transistor T5 may be connected to the driving voltage line PL and the first transistor T1. The fifth transistor T5 may include a gate connected to the third gate line EML, a first terminal connected to the driving voltage line PL, and a second terminal connected to the first terminal of the first transistor T1. The fifth transistor T5 may be turned on or off depending on the third gate signal EM transmitted to the third gate line EML.

The sixth transistor T6 may be connected to the first transistor T1 and the light-emitting diode ED. The sixth transistor T6 may be connected between the second node N2 and the third node N3. The sixth transistor T6 may include a gate connected to the fifth gate line EMBL, a first terminal connected to the second node N2, and the second terminal connected to the third node N3. The first terminal of the sixth transistor T6 may be connected to the second terminal of the first transistor T1, the storage capacitor Cst, and the holding capacitor Chold. The second terminal of the sixth transistor T6 may be connected to the first terminal of the fourth transistor T4 and the pixel electrode of the light-emitting diode ED. The sixth transistor T6 may be turned on or off depending on the fifth gate signal EMB transmitted to the fifth gate line EMBL.

The storage capacitor Cst may be connected between the gate of the first transistor T1 and the second terminal of the first transistor T1. A first electrode of the storage capacitor Cst may be connected to the first node N1, and a second electrode may be connected to the second node N2. The first electrode of the storage capacitor Cst may be connected to the gate of the first transistor T1, the second terminal of the second transistor T2, and the first terminal of the third transistor T3. The second electrode of the storage capacitor Cst may be connected to the second terminal of the first transistor T1, the first-second gate, the second electrode of the holding capacitor Chold, and the first terminal of the sixth transistor T6. The storage capacitor Cst may store a voltage corresponding to the threshold voltage of the first transistor T1 and the data signal Dm.

When the third transistor T3 and the fifth transistor T5 are turned on, the first transistor T1 may be turned on. When the voltage of the second terminal of the first transistor T1 drops to the difference (Vref-Vth1) between the reference voltage Vref and the threshold voltage Vth1 of the first transistor T1, the first transistor T1 is turned off, and a voltage corresponding to the threshold voltage Vth1 of the first transistor T1 is stored in the storage capacitor Cst, so that the threshold voltage Vth1 of the first transistor T1 may be compensated.

The holding capacitor Chold may be connected between the driving voltage line PL and the second node N2. A first electrode of the holding capacitor Chold may be connected to the driving voltage line PL. A second electrode of the holding capacitor Chold may be connected to the second terminal of the first transistor T1, the first-second gate, the second electrode of the storage capacitor Cst, and the first terminal of the sixth transistor T6.

The capacitance of each of the storage capacitor Cst and the holding capacitor Chold may vary depending on the color of light emitted from the light-emitting diode ED.

The auxiliary capacitor Ca may be electrically connected to the sixth transistor T6, a sustain voltage line VSSL, and the pixel electrode of the light-emitting diode ED. The auxiliary capacitor Ca stores and maintains a voltage corresponding to the voltage difference between the pixel electrode of the light-emitting diode ED and the sustain voltage line VSSL, thereby preventing or reducing the problem of the black brightness increasing when the sixth transistor T6 is turned off.

The light-emitting diode ED may be connected to the first transistor T1 through the sixth transistor T6. The light-emitting diode ED includes the pixel electrode (anode) connected to the third node N3 and a counter electrode (cathode) facing the pixel electrode, and the counter electrode may be supplied with a common voltage ELVSS. As an example, the counter electrode (cathode) may be electrically connected to the sustain voltage line VSSL that extends into the display area and provides the common voltage ELVSS. The driving current output by the first transistor T1 flows through the light-emitting diode ED by the turned-on fifth transistor T5 and the turned-on sixth transistor T6, and the light-emitting diode ED may emit light with a brightness corresponding to the size of the driving current.

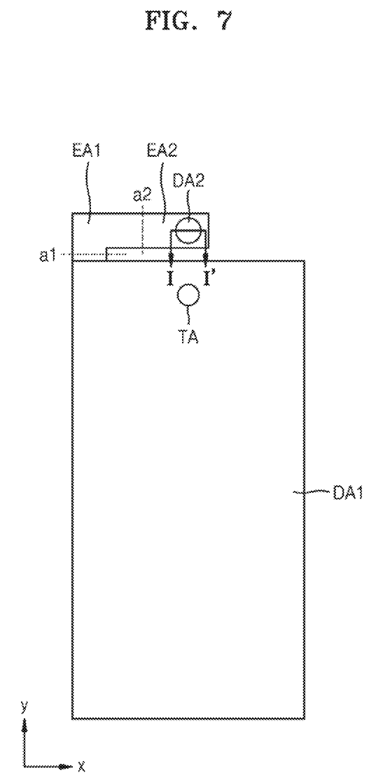

FIG. 7 schematically illustrates a front view of a display panel according to some embodiments. For example, FIG. 7 schematically illustrates an unfolding diagram of a display panel including a first edge area and a second edge area.

Referring to FIG. 7, the display panel 10 may include a first display area DA1 and a transmission area TA. The first display area DA1 may be arranged to surround the transmission area TA.

The first edge area EA1 and the second edge area EA2 may extend from the first display area DA1. The first edge area EA1 and the second edge area EA2 may be arranged on one side of the first display area DA1. The second edge area EA2 may include a second display area DA2.

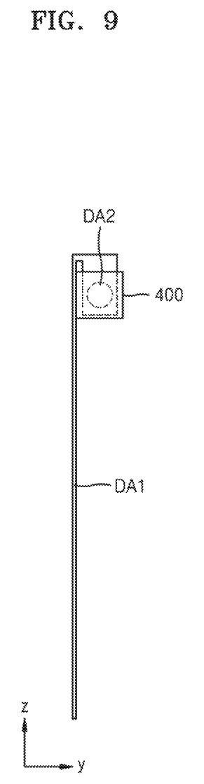

According to some embodiments, the first edge area EA1 may be folded along the first line a1, and the second edge area EA2 may be folded along the second line a2. A side view of the display device 1 after the display panel 10 is folded along the first line a1 and the second line a2 is illustrated in FIG. 9, which will be described in more detail later.

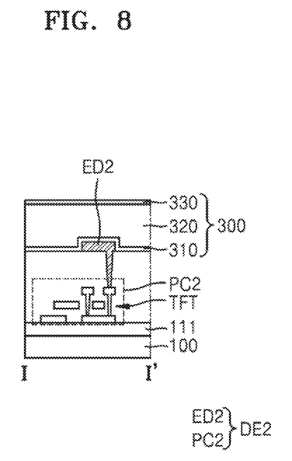

FIG. 8 is a schematic cross-sectional view of a second display area of a display panel according to some embodiments.

The second display area DA2 may include a second display element DE2. The second display element DE2 may include a second light-emitting diode ED2 and a second pixel circuit PC2 electrically connected thereto.

The second display area DA2 may include a substrate 100, the second pixel circuit PC2 including a thin film transistor TFT located on the substrate 100, the second light-emitting diode ED2 electrically connected to the second pixel circuit PC2, and a thin film encapsulation layer 300 covering the second display element DE2.

The substrate 100 may include glass or polymer resin. The substrate 100 including a polymer resin may have flexible, foldable, rollable, or bendable properties. The substrate 100 may have a multilayer structure including a layer including the aforementioned polymer resin and an inorganic layer.

The thin film transistor TFT and the second light-emitting diode ED2 as a display element electrically connected to the thin film transistor TFT may be located on an upper surface of the substrate 100.

The second light-emitting diode ED2 may be an organic light-emitting diode containing an organic material. Organic light-emitting diodes may emit red, green, or blue light. The second light-emitting diode ED2 may be an inorganic light-emitting diode containing an inorganic material. The inorganic light-emitting diode may include a PN junction diode including inorganic semiconductor-based materials. When voltage is applied in the forward direction to a PN junction diode, holes and electrons are injected, and the energy generated by the recombination of the holes and electrons is converted into light energy, which may emit light of 14 specific colors. The aforementioned light-emitting diodes may have a width of several to several hundred micrometers or several to several hundred nanometers. In some embodiments, the second light-emitting diode ED2 may include a quantum dot light-emitting diode. The light-emitting layer of the second light-emitting diode ED2 may include an organic material, an inorganic material, quantum dots, an organic material and quantum dots, or an inorganic material and quantum dots.

The second light-emitting diode ED2 may be electrically connected to the thin film transistor TFT located underneath it. In this regard, FIG. 4 illustrates that a buffer layer 111 is located on the substrate 100 and the thin film transistor TFT is located on the buffer layer 111.

The thin film encapsulation layer 300 may cover the second light-emitting diodes ED2. The thin film encapsulation layer 300 may include at least one inorganic encapsulation layer and at least one organic encapsulation layer. According to some embodiments, the thin film encapsulation layer 300 may include a first and second inorganic encapsulation layers 310, 330 and an organic encapsulation layer 320 therebetween.

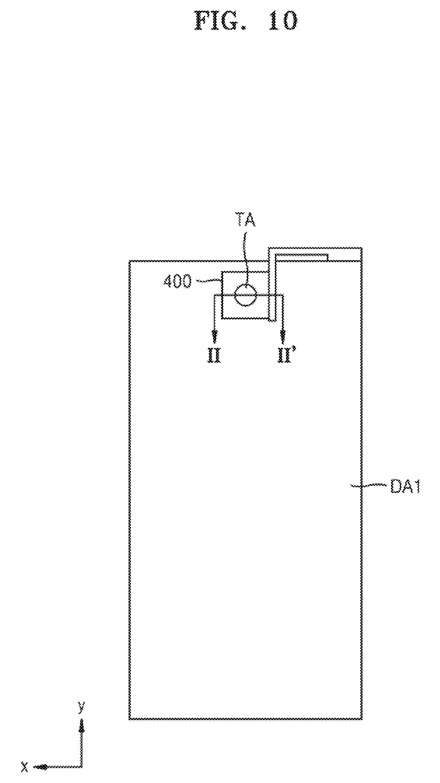

FIG. 9 is a schematic side view of a display device according to some embodiments. FIG. 10 schematically illustrates a rear view of a display device according to some embodiments.

Referring to FIGS. 9 and 10, the first edge area EA1 may extend from the first display area DA1 and be positioned on one side of the first display area DA1. The second edge area EA2 may extend from the first edge area EA1 and be located below the first display area DA1.

A prism unit 400 may be located below a transmission area TA. The second edge area EA2 may be spaced apart from the prism unit 400 in the first direction (e.g., x direction). The second edge area EA2 may include the second display area DA2. The second display area DA2 may also be spaced apart from the prism unit 400 in the first direction (e.g., x direction).

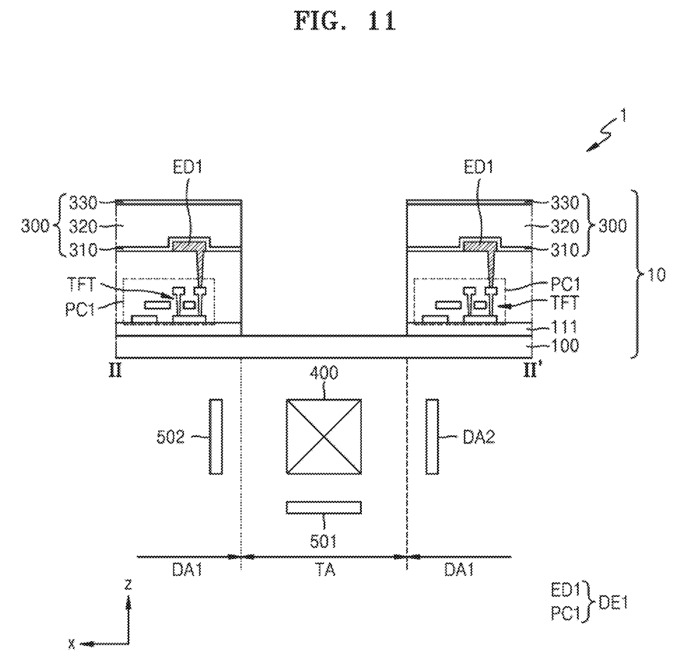

FIG. 11 is a schematic cross-sectional view of a first display area and a transmission area of a display device according to some embodiments.

Referring to FIG. 11, the first display area DA1 may include a first display element DE1. The first display element DE1 may include a first light-emitting diode ED1 and a first pixel circuit PC1 electrically connected thereto.

The transmission area TA may be an area where no display elements are placed. For example, the transmission area TA may be an area where light-emitting diodes and pixel circuits are not arranged. The transmission area TA may be an area through which light directed to a sensor unit 501 or a camera unit 502 may be transmitted, and may be an area through which light emitted from the second display element DE2 of the second display area DA2 may be reflected by the prism unit 400 and transmitted. The transmittance of the transmission area TA may be about 30% or more, about 40% or more, about 50% or more, about 60% or more, about 70% or more, about 75% or more, about 80% or more, about 85% or more, or about 90% or more.

The prism unit 400 may be located below the transmission area TA. The second display area DA2 may be spaced apart from the prism unit 400 in the first direction (e.g., x direction). The camera unit 502 may be spaced apart from the prism unit in the first direction (e.g., -x direction). The sensor unit 501 may be located below the prism unit 400. However, the disclosure is not limited thereto. According to some embodiments, the second display area DA2 may be spaced apart from the prism unit 400 in the first direction (e.g., in the x direction), the sensor unit 501 may be spaced apart from the prism unit 400 in the first direction (e.g., in the -x direction), and the camera unit 502 may be located below the prism unit 400.

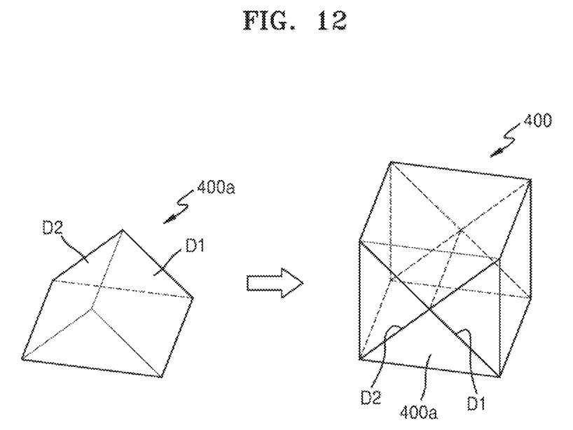

FIG. 12 is a perspective view schematically illustrating that the prism unit is composed of four prisms.

Referring to FIG. 12, the prism unit 400 may be included with four prism 400a. The prism 400a may be formed in the shape of a triangular prism. The prism 400a may include a first side surface D1 and a second side surface D2. The first side surface D1 and the second side surface D2 may be inclined surfaces.

The prism unit 400 may have a shape in which the first side surface D1 or the second side surface D2 of each of four prisms 400a in the shape of the triangular prism are in contact with each other. The prism unit 400 may be formed in a hexahedral shape.

The first side surface D1 and the second side surface D2 of the prism 400a may be film coated. The first side surface D1 and the second side surface D2 of the prism 400a are film-coated so that the reflectivity on the first side surface D1 or the second side surface D2 of the prism 400a of light transmitted through the transmission area TA reflected from the may be controlled, or the reflectivity on the first side surface D1 or the second side surface D2 of the prism 400a of light emitted from the second display element (DE2, see FIG. 8) of the second display area DA2 may be controlled. In addition, the first side surface D1 and the second side surface D2 of the prism 400a are film-coated, so that the transmittance of light transmitted through the transmission area TA may be controlled through the first side surface D1 or the second side surface D2 of the prism 400a.

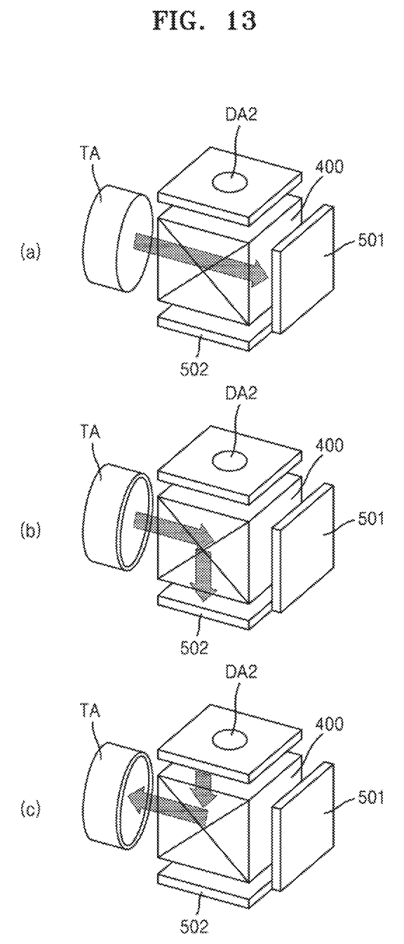

FIG. 13 is a perspective view schematically illustrating the path of light when a camera unit, a sensor unit, and a second display area are driven. For example, (a) of FIG. 13 schematically illustrates the path of light when the sensor unit is driven, (b) schematically illustrates the path of light when the camera unit is driven, and (c) schematically illustrates the path of light when the second display element of the second display area is driven.

Referring to (a) of FIG. 13, when the sensor unit 501 is driven, light that has passed through the transmission area TA may pass through the prism unit 400 and enter the sensor unit 501. For example, light that has passed through the transmission area TA may pass through the first side surface D1(see FIG. 12) or the second side surface D2(see FIG. 12) of the prism 400a(see FIG. 12) of the prism unit 400 and enter the sensor unit 501. The transmittance of light passing through the transmission area TA in the prism unit 400 may be controlled through film coating on the first side surface D1 or the second side surface D2 of the prism 400a. When the sensor unit 501 is driven, light passing through the transmission area TA must be incident on the sensor unit 501, so the second display element DE2(see FIG. 8) of the second display area DA2 may not be driven.

Referring to (b) of FIG. 13, when the camera unit 502 is driven, light that has passed through the transmission area TA may be reflected by the prism unit 400 and enter the camera unit 502. For example, light passing through the transmission area TA may be reflected from the first side surface or the second side surface of the prism 400a of the prism unit 400 and enter the camera unit 502. The reflectivity of light passing through the transmission area TA at the prism unit may be controlled by film coating on the first side surface D1 or second side surface D2 of the prism 400a. When the camera unit 502 is driven, light passing through the transmission area must be incident on the camera unit 502, so the second display element DE2 of the second display area DA2 may not be driven.

Referring to (c) of FIG. 13, when the second display element DE2 of the second display area DA2 is driven, light emitted from the second display element DE2 may be reflected from the prism unit 400 and enter the transmission area TA. For example, light emitted from the second display element DE2 may be reflected from the first side surface D1 or the second side surface D2 of the prism 400a of the prism unit 400 and enter the transmission area TA. The reflectivity of light emitted from the second display element DE2 at the prism unit 400 may be controlled by film coating on the first side surface D1 or the second side surface D2 of the prism 400a. When the second display element DE2 of the second display area DA2 is driven, the light emitted from the second display element DE2 must be incident toward the transmission area TA, so the camera unit 502 and the sensor unit 501 may not be driven.

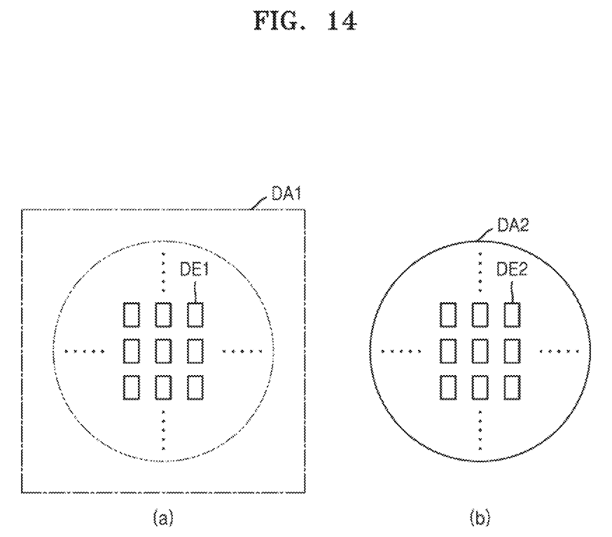

FIG. 14 shows a schematic cross-sectional view of a first display element in a first display area arranged and a schematic cross-sectional view of a second display element in a second display area arranged.

Referring to FIG. 14, a number of the first display elements DE1 per unit area of the first display area DA1 and a number of the second display elements DE2 per unit area of the second display area DA2 may be the same. In other words, the resolution of the second display area DA2 may be the same as the resolution of the first display area DA1.

In the case of a display device that does not use a prism unit, display elements may be placed in the transmission area. In order to increase the transmittance of the transmission area, the number of display elements per unit area of the transmission region may be smaller than the number of first display elements per unit area of the first display area. The resolution of the transmission area may be smaller than the resolution of the first display area.

According to some embodiments, the prism unit 400 may be located below the transmission area TA, and the second display area DA2 having the same resolution as the first display area DA1 may be spaced apart from the prism unit 400 in the first direction (e.g., the x direction). Because the light emitted by the second display element DE2 of the second display area DA2 having the same resolution as the first display area DA1 is reflected by the prism unit 400 and passes through the transmission area TA, the resolution in the transmission area TA may be the same as the resolution of the first display area DA1. The resolution of the transmission area TA may be relatively improved by using the prism unit 400.

Additionally, because the second display element DE2 is placed separately in the second edge area EA2, the transmission area TA may not include the display element. Because the transmission area TA does not include the display element, the transmittance of the transmission area TA is relatively improved, so that the quality of the sensor unit 501 or the camera unit 502 may be relatively improved.

According to some embodiments as described above, a display device with relatively improved reliability and quality and an electronic device including the same may be implemented. Of course, the scope is not limited by these effects.

Although the disclosure has been described with reference to the embodiments shown in the drawings, these are merely examples, and those skilled in the art will understand that various modifications and equivalent other embodiments are possible therefrom. Therefore, the true technical protection scope should be determined by the technical idea of the attached patent claims, and their equivalents.

What is claimed is:

1. A display device, comprising:
a display panel including a transmission area and a first display area surrounding the transmission area;
a prism unit comprising four triangular prisms and located below the transmission area;
a second display area spaced apart from the prism unit in a first direction;
a camera unit arranged spaced apart from the prism unit in the first direction; and
a sensor unit below the prism unit,
wherein a first side surface and a second side surface of the prism are film-coated.

2. The display device of claim 1, wherein the prism unit has a shape so that first side surfaces or second side surfaces of the four prisms are in contact with each other.

3. The display device of claim 2, wherein the prism unit has a hexahedral shape.

4. The display device of claim 1, wherein
the first display area includes a first display element, and
the first display element includes a first light-emitting diode and a first pixel circuit electrically connected to the first light-emitting diode.

5. The display device of claim 4, wherein
the second display area includes a second display element, and
the second display element includes a second light-emitting diode and a second pixel circuit electrically connected to the second light-emitting diode.

6. The display device of claim 5, wherein a number of the second display elements per unit area in the second display area is equal to a number of the first display elements per unit area in the first display area.

7. The display device of claim 1, wherein light transmitted through the transmission area is configured to be reflected from the first side surface or the second side surface of the prism of the prism unit and to enter the camera unit.

8. The display device of claim 1, wherein light transmitted through the transmission area is configured to pass through the first side surface or the second side surface of the prism of the prism unit and to enter the sensor unit.

9. The display device of claim 1, wherein light emitted from the second display area is configured to be reflected from the first side surface or the second side surface of the prism of the prism unit and to enter the transmission area.

10. The display device of claim 5, wherein the second display element of the second display area is configured to not be driven based on the camera unit being driven.

11. The display device of claim 5, wherein the second display element of the second display area is configured to not be driven based on the sensor unit being driven.

12. The display device of claim 5, wherein the camera unit and the sensor unit are configured to not be driven based on the second display element of the second display area being driven.

13. The display device of claim 1, wherein the display panel includes a first edge area extending from the first display area.

14. The display device of claim 13, wherein the first edge area is on one side of the first display area.

15. The display device of claim 13, wherein the display panel includes a second edge area extending from the first edge area and located below the first display area.

16. The display device of claim 15, wherein the second edge area includes a second display area.

17. An electronic device, comprising:
a display panel including a transmission area and a first display area surrounding the transmission area;
a prism unit comprising four triangular prisms and located below the transmission area;
a second display area spaced apart from the prism unit in a first direction;
a camera unit spaced apart from the prism unit in the first direction; and
a sensor unit below the prism unit, wherein
a first side surface and a second side surface of the prism are film-coated,
and the prism unit has a shape so that first side surfaces or second side surfaces of the four prisms are in contact with each other.

18. The electronic device of claim 17, wherein
a number of second display elements per unit area in the second display area is equal to a number of first display elements per unit area in the first display area.

19. The electronic device of claim 17, wherein
the display panel includes a first edge area extending to the first display area and a second edge area extending from the first edge area and located below the first display area.

20. The electronic device of claim 19, wherein the second edge area includes a second display area.
